(19) United States
(12) Patent Application Publication
(10) Pub. No.: US 2015/0115476 A1
(43) Pub. Date: Apr. 30, 2015

(54) Module with Stacked Package Components

(71) Applicant: Innovative Turnkey Solution Corporation, Hsinchu City (TW)

(72) Inventor: Shih-Chi CHEN, Hsinchu City (TW)

(73) Assignee: Innovative Turnkey Solution Corporation, Hsinchu City (TW)

(21) Appl. No.: 14/137,281

(22) Filed: Dec. 20, 2013

(30) Foreign Application Priority Data
Oct. 24, 2013 (TW) 102138353

(51) Int. Cl. H01L 25/065

(52) U.S. Cl. CPC H01L 25/0657
USPC 257/777

(57) ABSTRACT

A module with stack package components includes: at least a package component in a loader. Moreover, each package components includes at least a chip. Package components stacks in the loader. The package components connect with the loader by metal connecters and wire. These package components are placed to make the loader be the module with stack package components. The module connects with some sockets by other metal connecters.

### FIELD OF THE INVENTION

The present invention relates to a stacked package module, and more particular to stack a plurality of package devices using a three-dimensional carrier to form a module with a stacked package device.

### BACKGROUND OF THE INVENTION

Modern life is inseparable from the large number of electronic products, and therefore the demand for the semiconductor industry, more and more, the semiconductor industry will continue to evolve to meet the market demand for a variety products, the most common needs of hope is that the product with better functionality is manufactured by the smaller space the same or even better product functionality.

The stacked chip package is a package method for reducing the space of the package product, the package method arranges a number of different dies with different function into a package module, in addition to achieve functional integration purposes, the space of circuit board can effectively save, and the space occupied by the chip can also be reduced, so as to reduce overall manufacturing costs. In addition, the circuit distance between the plurality of dies in the package can be short to provide the better electrical performance, and the signal propagation is interfered in the circuit can be effectively reduced.

Currently, the mostly package method of the stacked chip package is memory chip package, such as flash memory and static random access memory are stacked each other. The part of the communications chip also utilizes the stacked wafer level package, for example, the base frequency, flash memory and static random access memory chips, which are configured into a single package.

However, the present stacked chip package still has some drawbacks, such as a wafer are stacked in each other processes, because the chip includes a lots of pads thereon, so as to the electric contacts between the wafer substrate (substrate) and the substrate is difficult, and thus yield is to be reduced. Furthermore, in order to enhance the connection between the wafers, the most common way is to increase the encapsulation process between the wafers, however, the excessive encapsulation glue will increase the thickness of the overall packaging products, and the reliability of the package product is also reduced. In addition, also, it is difficult process to bonding the metal wired on the stacked wafers. In addition, when the packaged product is assembled to other electronic device such as circuit board, which needs the alignment to align the joint and the pads, such that the cost of packaging is to be increased. For the above disadvantages, there is a need for improvement.

### SUMMARY OF THE INVENTION

In order to solve the aforementioned drawbacks, the present invention provides a module with a plurality of stacked package devices with the design of three-dimensional carrier to simply the stacked package device manufacturing process and the reliability of the package product can be improved.

According to above objects, the present invention provides a module with a plurality of stacked package devices which includes a carrier having a first surface and a second surface opposite to the first surface, a recess is formed in the first surface of the recess and an edge is disposed around the recess such that a chip arrangement region is formed in the recess and a plurality of first metal connections is disposed on a bottom of the recess, the plurality of first metal connections is redistributed on two sides of the recess to allow a first recess walls that is formed between the first pair of platforms and the chip arrangement region, and a pair of second recess walls is formed between edge and the pair of first platforms and the plurality of first metal connections is exposed, a height of the pair of first platforms is higher than that of the chip arrangement region and a plurality of second metal connections is disposed on the pair of first platforms respectively, in which each the plurality of first metal connections on same side is corresponding to each the plurality of second metal connections, and each the plurality first metal connections is electrically connected with each the plurality of second metal connections by a plurality of first metal wires. A first chip having a top and a bottom and a plurality of second pads on the bottom of the first chip and the first chip is flipped on the chip arrangement region to allow the plurality of first pads that is electrically connected with the plurality of first metal connections. A package device having a second chip and a substrate. The second chip having a top and a bottom, and a plurality of second pads on the bottom of the second chip. The substrate having a third surface and a fourth surface opposite to the third surface and a plurality of substrate through hole is passed through the third surface to the fourth surface of the substrate and the plurality of chip connections on the third surface of the substrate. The plurality of chip connections is extended from the plurality of substrate through holes to the fourth surface of the substrate to form a plurality of carrier connections, in which the plurality of chip connections is electrically connected with the plurality of second pads of the second chip and the plurality of carrier connections is electrically connected with the plurality of second metal connections. Each the plurality of second metal connections is further electrically connected with the plurality of second metal wires and the plurality of second metal wires is extended from the first platform of the carrier through the edge to the second surface of the carrier and each the plurality of second metal wires is on one end of second surface to form a plurality of third metal connections.

The present invention further provides a module with a plurality of stacked package device. A carrier having a first surface and a second surface opposite to the first surface and a recess is formed on the first surface and an edge is disposed around the recess such that a chip arrangement region is formed in the recess. A plurality of first metal connections is disposed on a bottom of the recess and a plurality of first metal connections is redistributed on two sides of the recess. A pair of first platforms is disposed adjacent on two sides of the chip arrangement region to allow a pair of first recess walls that is formed between the pair of first platforms and the chip arrangement region and a pair of second recess walls is disposed between the edge and the pair of the first platforms and the plurality of first metal connections is exposed. A height of the pair of platforms is higher than that of the chip arrangement region and a plurality of second metal connections is disposed on the pair of first platforms respectively, in which each the plurality of first metal connections is corresponding to each the plurality of second metal connections on same side, and each the plurality of first metal connections is electrically connected with the plurality of second metal connections by a plurality of first metal wires. A first chip having a top and a bottom and a plurality of first pads is disposed on the bottom. The first chip is flipped on the chip arrangement region to allow the plurality of first pads that is electrically connected with the plurality of first metal connections. A package device having a pair of second chips and a substrate. Each the pair of second chips having a top and a bottom and a plurality of second pads is disposed on the bottom of each the pair of second chips. The substrate having a third surface and a fourth surface opposite to the third surface and a plurality of substrate through holes is passed through from the third surface to the fourth surface. The third surface of the substrate having a plurality of first chip connections which is extended to the fourth surface of the substrate through the plurality of substrate through holes to the fourth surface to form a plurality of first carrier connections, in which the plurality of first chip connections is electrically connected with the plurality of second pads of the pair of second chips and the plurality of first carrier connections is electrically connected with plurality of second metal connections of the carrier. Each the plurality of second metal connections is further electrically connected with the plurality of second metal wires and the plurality of metal wires is extended from the first platform of the carrier through the edge to the second surface of the carrier and each the plurality of second metal wires is on one end of the second surface of the carrier is to form a plurality of third metal connections.

The present invention also provides a module with a plurality of stacked package device. A carrier having a first surface and a second surface to the first surface. A recess is formed on the first surface of the carrier and an edge is disposed around the recess such that a chip arrangement region is disposed in the recess and a plurality of first metal connections is disposed in the bottom of the recess. The plurality of first metal connections is redistributed on two sides of the recess. A pair of first platforms are disposed adjacent on two sides of the chip arrangement region to allow a pair of first recess walls that is formed between the pair of first platforms and the chip arrangement region and a pair of second recess walls that is formed between the edge and the pair of first platforms and the plurality of first metal connections is exposed. A height of the pair of first platforms is higher than that of the chip arrangement region. A plurality of second metal connections is disposed on the pair of first platforms respectively, in which each the plurality of first metal connections on same side is corresponding to each the plurality of second metal connections. A first chip having a top and a bottom and a plurality of pads is disposed on the bottom of the first chip to allow the plurality of first pads that is electrically connected with the plurality of first metal connections. A package device includes a second chip and a substrate. The second chip having a top and a bottom and a plurality of second pads is disposed on the bottom of the second chip. The substrate having a third surface and a fourth surface opposite to the third surface and a plurality of substrate through holes is passed through from the third surface to the fourth surface. The third surface includes a plurality of chip connections that is extended to the fourth surface through the plurality of substrate through holes to form a plurality of carrier connections, in which the plurality of chip connections is electrically connected with the plurality of second pads of the second chip and the plurality of carrier connections is electrically connected with the plurality of second metal connections of the carrier. The carrier further includes a plurality of carrier through holes which is passed through from the first surface to the second surface and both each the plurality of first metal connections and each the plurality of second metal connections are extended from each the plurality of corresponded carrier through hole to the second surface of the carrier to form a plurality of third metal connections.

According to the module with a stacked package device of the present invention, the package vendor only assembles the stacked device module with the carrier during the packaging process and further assembles the substrate with the carrier, in which the carrier and the substrate can be performed via the standardized process by other manufacture vendor to decrease the packaging cost.

In addition, for the module with stacked package device of the present invention, the chip or package device is fully disposed in the carrier after packaging process and the molding process is not required, such that the material of the molding process can be saved and the manufacture cost can also be reduced.

For the module with the stacked package device of the present invention, the chip or package device is fully disposed in the carrier after package process which is not affected by external substance such that the reliability of the module with the can be increased.

For the module with a stacked package device of the present invention, the carrier and the substrate can be manufactured via the standardized process, such that the product size also can be standardized, and time required for the wire bonding and the alignment can also be decreased, and the yield of the package vendor can be increased.

### BRIEF DESCRIPTION OF THE DRAWINGS

The present invention will be apparent to those skilled in the art by reading the following description of a preferred embodiment thereof with reference to the drawings, in which:

FIG. 1 is a top view of the carrier in accordance with present invention;

FIG. 2A is a first embodiment of the top view of the carrier in accordance with the present invention;

FIG. 2B is a vertical view of the carrier in accordance with the present invention;

FIG. 3 is a vertical view of the chip in accordance with the present invention;

FIG. 4A is a first embodiment of the top view of the substrate in accordance with the present invention;

FIG. 4B is a first embodiment of the vertical view of the substrate in accordance with the present invention;

FIG. 5 shows a cross-sectional view of a first embodiment of a package device in accordance with the present invention;

FIG. 6A is a cross-sectional view of a first embodiment of the module with a plurality of stacked package devices in accordance with the present invention;

FIG. 6B is cross-sectional view of a first embodiment of the module with the plurality of stacked package devices in accordance with the present invention;

FIG. 7 is vertical view of a second embodiment of the chip in accordance with the present invention;

FIG. 8 is a cross-sectional view of a second embodiment of the package device in accordance with the present invention;

FIG. 9 is a cross-sectional view of s second embodiment of the module with a plurality of stacked package devices in accordance with the present invention;

FIG. 10A is a top view of the second embodiment of the substrate in accordance with the present invention;

FIG. 10B is a bottom view of the second embodiment of the substrate in accordance with the present invention;

FIG. 11 is a cross-sectional view of a third embodiment of the package device in accordance with the present invention;

FIG. 12 is a cross-sectional view of the third embodiment of the module with a plurality of stacked package devices in accordance with the present invention;

FIG. 13A is a top view of the second embodiment of the carrier in accordance with the present invention;

FIG. 13B is a vertical view of the second embodiment of the carrier in accordance with the present invention; and

FIG. 14 is a cross-sectional view of the forth embodiment of the module with the plurality of stacked package devices in accordance with the present invention.

### DETAILED DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

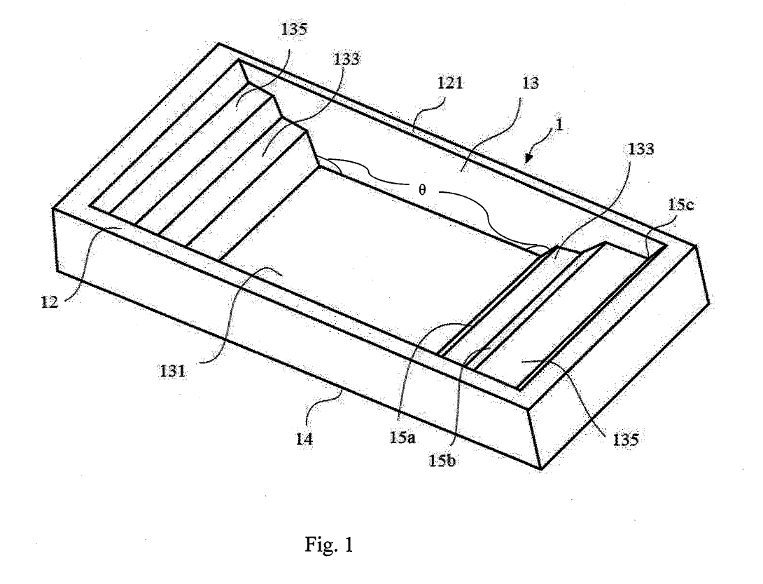

Please refer to FIG. 1. FIG. 1 is a top view of the carrier of the present invention. As shown in FIG. 1, the carrier 1 is formed by polymer injection molding method, and the material of the polymer is polyimide ammonium. The carrier 1 has a first surface 12 and a second surface 14 opposite to the first surface 12. A recess 13 is disposed on the first surface 12 and an edge 121 is disposed around the recess 13. The bottom of the recess 13 is a chip arrangement region 131. A first platform 133 and a second platform 135 are disposed on two opposite sides in the recess 13 respectively. The first platform 133 is disposed adjacent to the chip arrangement region 131. Obviously, the chip arrangement region 131 is disposed in the middle of the first platforms 133 on the two sides and the height of the first platform 133 is higher than that of the chip arrangement region 131. In one embodiment, the height of the first platform 133 can be designed as the same that of the chip which is to be packaged or is identical to that of the other package device. Then, the second platform 135 is disposed adjacent to the first platform 133. Obviously, the first platform 133 and the chip arrangement region 131 are disposed in the middle of the second platforms 135 on two sides. Similarly, the height of the second platform 135 is higher than that of the first platforms 133. In one embodiment, the height of the second platform 135 can be designed as same that of the chip which is to be packaged or is identical to other package device. According to aforementioned, the chip arrangement region 131, the first platform 133 and the second platform 135 can be formed as a stepped structure on two opposite sides of the recess 13. In addition, the recess wall 15a between the chip arrangement region 131 and the any first platform 133, the recess wall 15b between the first platform 133 and the second platform 135 adjacent to the first platform 133, the recess wall 15c between any second platform 135 and the first surface 12 adjacent to the first surface are inclined. The angle between each recess walls 15a, 15b,15c and each planes is denoted as 0, in which the angle θ is in range from 90 degree to 135 degree and can be expressed as 90□≦θ≦135□, that is, each recess wall 15a, 15b, 15c can be the vertical. It is noted to illustrate that the angle between each recess wall 15a, 15b, 15c and each planes of the recess 13 is not limited herein. The purpose for disposing the recess wall 15a, 15b, and 15c is used to assist the location and the alignment of the chip.

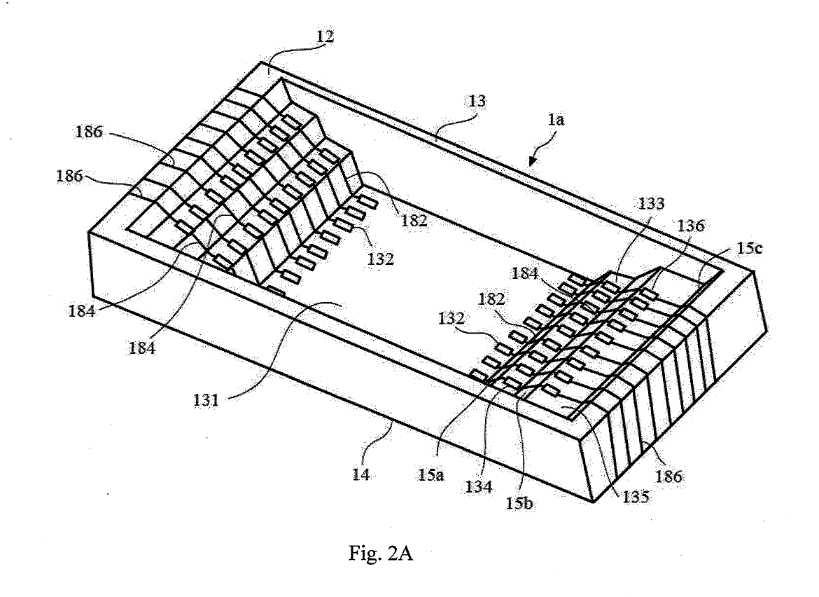

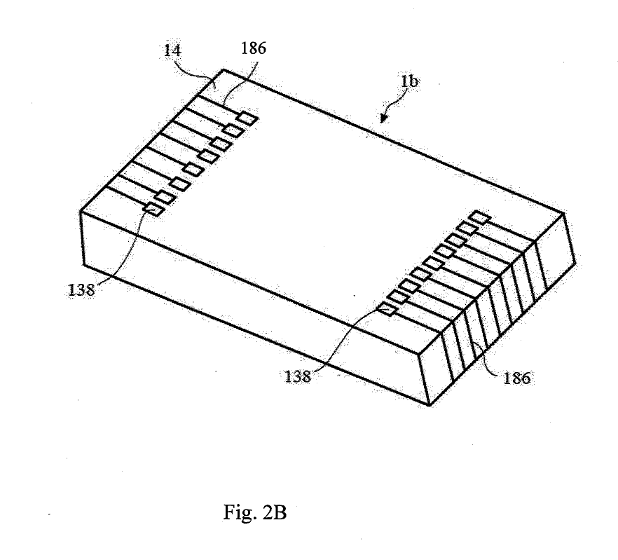

Next, please refer to FIG. 2A and FIG. 2B. FIG. 2A is a first embodiment of a top view of the carrier of the present invention and FIG. 2B is a first embodiment of a vertical view of the carrier of the present invention. First, as shown in FIG. 2, a plurality of metal connections 132 is disposed on the chip arrangement region 131 of the carrier 1a and adjacent to two sides of the first platform 133. The plurality of metal connections 134 is disposed on the first platform 133 and a plurality of metal connections 136 is also disposed on the second platform 135. Meanwhile, the number of the plurality of metal connections 132, the plurality of metal connections 134, and the plurality of metal connections 136 are the same. The location of each the plurality of metal connections 132, the plurality of metal connections 134, and the plurality of metal connections 136 are corresponding to each other. In addition, each the plurality of metal connections 132 is electrically connected with each the plurality of metal connections 134 through the plurality of metal wires 182, and each the plurality of metal connections 134 is electrically connected with each the plurality of metal connections 136 through the plurality of metal wires 184. Each the plurality of metal connections 136 is further electrically connected with the plurality of metal wires 186, in which the plurality of metal wires 186 is extended from the second platforms 135 through the recess walls 15c, the edge 121 of the first surface 12 to the second surface 14 of the carrier 1a, and the plurality of metal connections 138 is disposed one end of each the plurality of the metal wires 186 to form a plurality of metal connections 138. That is, the plurality of metal connections 138 is disposed on the second surface of the carrier 1a in a neatly arrangement as shown in FIG. 2B. The arrangement of the plurality of metal connections 136 and the plurality of metal connections 138 on the second surface 12 is not to be limited herein. For example, the plurality of metal connections 138 can dispose adjacent to the peripheral of the second surface 14 of the carrier 1a.

Then, the formation of the plurality of metal connections 182, 184, 186 includes the location of the plurality of metal wires 182, 184, 186 that is first formed by laser engraving and then by using electroplating. For example, the recess wall 15a between the plurality of metal connections 132 and the plurality of metal connections 134 is engraved to form a location of the plurality of metal wires 182 and then a plurality of metal wires 182 is plated thereon. In one embodiment, the recess wall 15a, 15b, and 15c are inclined respectively to increase the plating efficiency of the plurality of metal wires 182, 184, and 186.

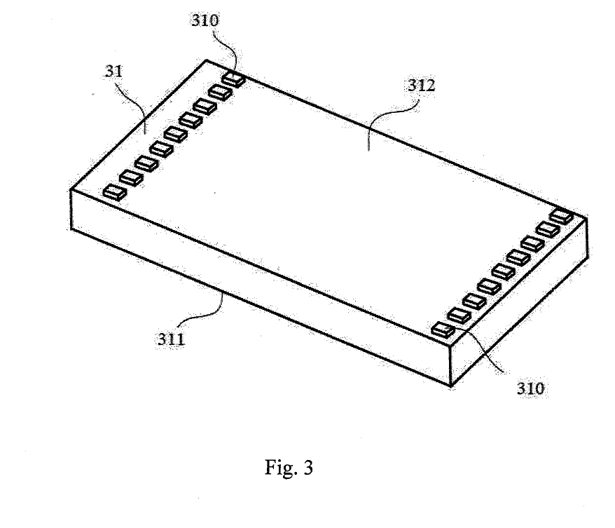

Next, please refer to FIG. 3. FIG. 3 is a vertical view of the chip. As shown in FIG. 3, the chip 31 is formed by cutting the wafer after accomplishing the semiconductor manufacturing. The chip 31 having a top 311 and a bottom 312 opposite to the top 311. A plurality of pads 310 is disposed on the bottom 312 of the chip 31. In an embodiment, each the plurality of pads 310 are disposed on two side of the chip 31 and is corresponding to the connection (not shown) of the desired chip arrangement region (not shown). For example, the arrangement of the plurality of pads 310 is corresponding to the plurality of metal connections 132 of the chip arrangement region 131. The number of the plurality of pads 310 and the arrangement on the chip 31 are not limited in this invention. Similarly, the number of the metal connections 132, 134, 136, 138 and the number of plurality of metal wires 182, 184, and 186 are corresponding to the different number of the plurality of pads 310.

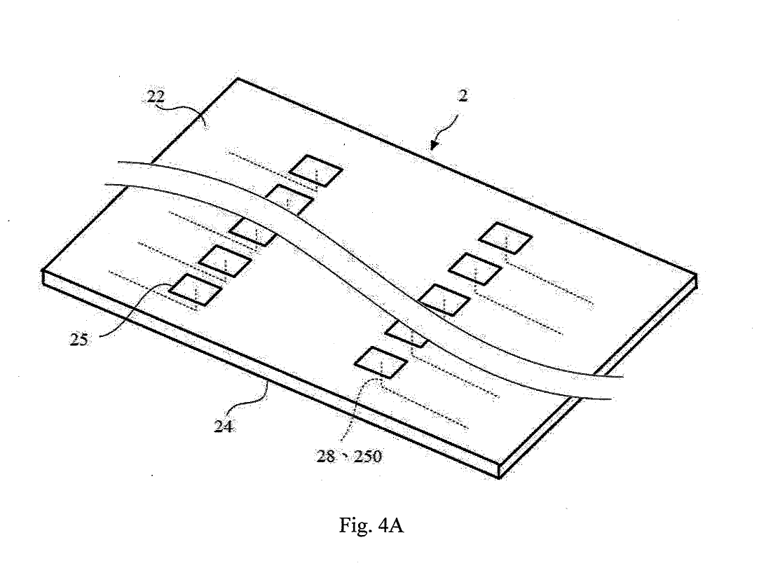

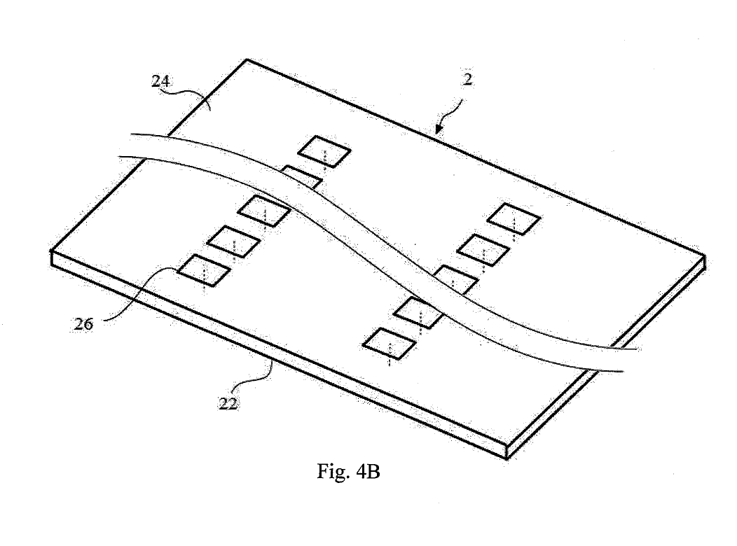

Next, please refer to FIG. 4A and FIG. 4B. FIG. 4A is a top view of a first embodiment of a substrate of the present invention and FIG. 4B is a vertical view of a first embodiment of a substrate of the present invention. As shown in FIG. 4A, the substrate includes a third surface 22 and a fourth surface 24 and the plurality of substrate through holes 28 is passed through the fourth surface 24 to the third surface 22. The plurality of chip connections 25 is disposed on the third surface 22 and the number of the plurality of chip connections and the arrangement are corresponding to the number of the plurality of chips on the substrate 2. For example, the chip 31 of FIG. 3 is arranged on the substrate 2 and the plurality of chip connections 25 on the third surface is corresponding to each the plurality of pads 310 to form an arrangement as shown in FIG. 4A. The fourth surface 24 of the substrate 2 includes a plurality of carrier connections 26 thereon and each the plurality of carrier connections 26 is electrically connected with the plurality of chip connections 25 by the metal material 250 within the plurality of substrate through holes 28. The arrangement of the plurality of carrier connections 26 is corresponding to the arranged location of the substrate 2. For example, when the substrate 2 is disposed across the chip arrangement region 131 and on the first platform 133, the number of the plurality of carrier connections 26 and the arrangement are corresponding to the plurality of metal connections 134 of the first platform 133. At the same time, the size of the substrate 2 is also corresponding to the distance of the first platform 133. In one embodiment of the present invention, the substrate 2 can be a multi-layers circuit board. In another embodiment, the substrate 2 can be a flexible printed circuit (FPC). Thus, the thickness of the module with the stacked package device can be reduced efficiency.

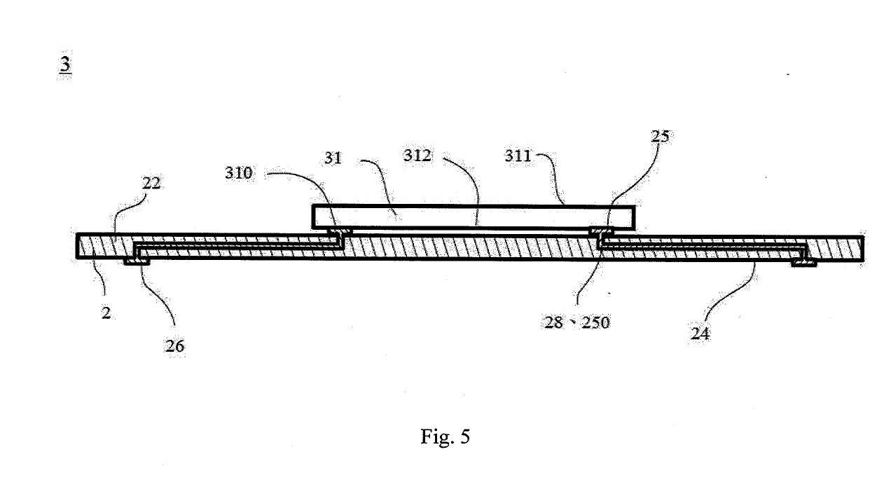

Then, please refer to FIG. 5 which is a cross-sectional view of the first embodiment of the package device of the present invention. As shown in FIG. 5, the package device 3 is composed of a chip 31 and a substrate 2. The bottom 312 of the chip 31 is opposite to the third surface 22 of the substrate 2. Meanwhile, each the plurality of pads 310 on the bottom 312 of the chip 31 is electrically connected with one of the plurality of chip connections 25 on the third surface 22. As discussion aforementioned, the substrate 2 can be formed with the different length according to the platform location of the carrier 1, and the size of the each substrate 2 is electrically connected with the chip 31 to form the package device 3 with different size.

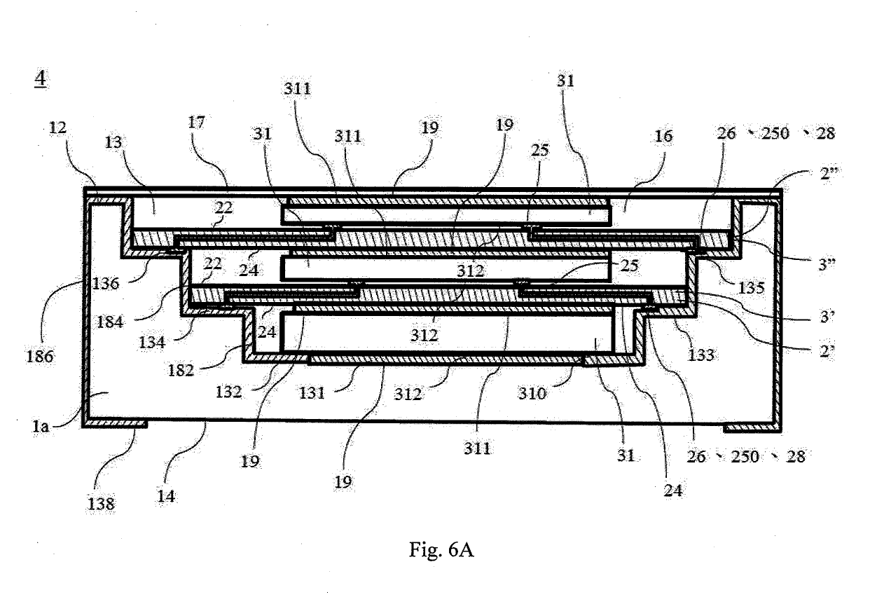

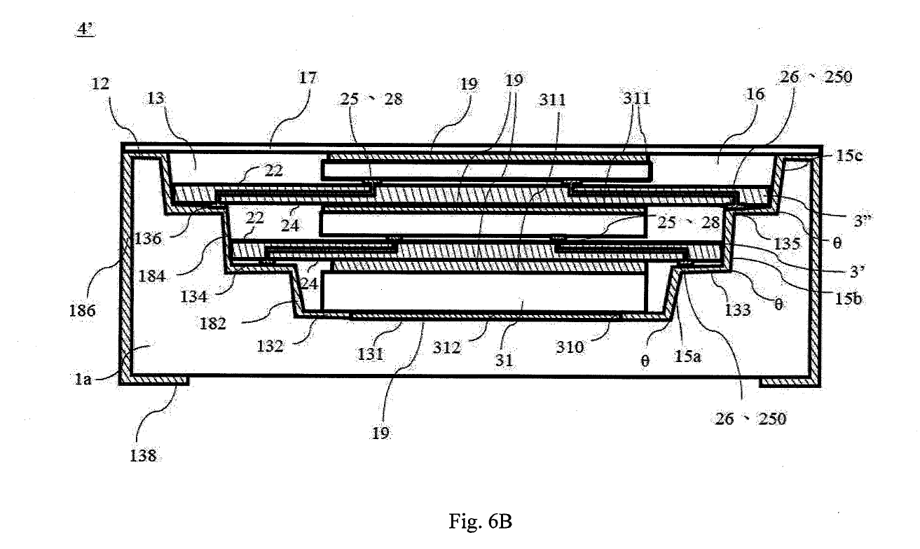

Next, please refer to FIG. 6A. FIG. 6A is a cross-sectional view of module with the stacked package device. As shown in FIG. 6, the module 4 with the plurality of stacked package devices is composed of a carrier 1a with the recess and at least one package device 3. Obviously, a plurality of chips is arranged in the module 4 with the plurality of stacked package devices, and the formation of each the package device is described later. First, a buffer material 19 is optionally formed on the first chip arrangement region 131. Then, the bottom of the chip 31 is aligned the chip arrangement region 131 to allow each the plurality of the pads 310 of the bottom 312 of the chip 31 that is electrically connected with one of the plurality of metal connections on the chip arrangement region 131 by using the flip chip process. Because the height between the first platform 133 and the chip arrangement region 131 can be designed as same as that of the chip 31, and the chip 31 can be fixed to the carrier 1a with using the buffer material 19. In one embodiment of the present invention, the buffer material 19 can be an adhesive material, such as epoxy or silicone. In addition, the buffer material 19 is optionally formed on the bottom 312 of the chip 31 and each the plurality of pads 310 being exposed. Then, the bottom 312 of the chip 31 is aligned the chip arrangement region 131 to allow each the plurality of pads 310 of the bottom 312 of the chip 31 that is electrically connected with one of the plurality of metal connections 132 on the chip arrangement region 131. Because the height between the first platform 133 and the chip arrangement region 131 can be designed as same as that of the chip 31, and the chip 31 can be fixed to the carrier 1a with using the buffer material 19. It is note to illustrate that by using the buffer material 19 to fix the chip 31 and the carrier 1a, the molding compound is not required for molding the chip 31. Thus, the package cost can be decreased.

Then, the first package device 3′ is connected the first platform 133 to allow the first package device 3′ that is stacked on the chip 31. The stacked method includes a fourth surface 24 of the substrate 2 of the first package device 3′ is disposed opposite to the first platform 133. Each the plurality of carrier connections 26 on the fourth surface 24 is electrically connected with one of the plurality of metal connections 133 on the first platform 133 respectively. In this embodiment, a buffer material 19 is optionally formed on the fourth surface 24 of the substrate 2′ such that when the plurality of carrier connections 26 on the substrate 2 of the first package 3′ is electrically connected with the plurality of metal connections 134 on the first platform 133, the substrate 2 of the first package device 3 is fixed the chip 31 on the first chip arrangement region 131 with using the buffer material 19. In addition, the buffer material 19 is not only used for fixing stack structure but also used for supporting the chip 31 of the first package device 3′ to prevent the vibration during the package process and damage the chip 31 of the first package device 3. Of course, the buffer material 19 is selectively formed on the top 311 of the lowermost chip 31. Thus, when the plurality of carrier connections 26 on the substrate 2′ of the first package device 3′ is electrically connected with the plurality of metal connections 134 on the first platform 133, the fourth surface 24 of the substrate is fixed with the chip 31 with using the buffer material 19 and the buffer material 19 can also support the chip 31 of the first package device 3. Thus, the buffer material 19 can fix the chip 31 and the substrate 2′ of the first package device 3′.

This section is used to illustrate the connection between the topmost second package device 3″ and the first package device 3′. Another buffer material 19 is formed on the top 311 of the chip 31 to avoid damaging the chip 31. Both the first package device 3′ and the second package device 3″ are disposed across the chip arrangement region 131 and disposed on the first platform 133 and the second platform 135 respectively, in which the fourth surface 24 of the substrate 2′ of the first package device 3′ is opposite to the first platform 133, and each the plurality of carrier connections 26 on the fourth surface 24 is electrically connected with one of the plurality of metal connections 134 on the first platform 133. Obviously, the second package device 3″ is disposed on the second platform 135 that is arranged by using the same arrangement, the buffer material 19 is first formed on the top 311 of the chip 31 of the first package device 3′ or the buffer material 19 can selectively form on the fourth surface 24 of the substrate 2″ of the second package device 3″ to avoid damaging the chip 31 of the first package device 3′ on the first platform 133 during the subsequent package process. The buffer material 19 is capable of fixing the chip 31 of the first package device 3 and the substrate 2″ of the second package device 3″, and the fourth surface 24 of the substrate 2″ of the second package device 3″ is disposed opposite to the second platform 135. Each the plurality of carrier connections 26 on the fourth surface 24 is electrically connected with one of the plurality of metal connections 136 on the second platform 135. Then, another buffer material 19 is formed on the top 311 of the chip 31 of the second package device 3″ to avoid damaging the chip 3″ of the second package device 3″ on the second platform 135 during the subsequent package process. After the first package device 3′, the second package device 3″ and the chip 31 are disposed in the recess 13 of the carrier 1a, the glue 16 is selectively filled with the recess 13 to encapsulate the first package device 3′, the second package device 3″, and the chip 3′ to protect the first package device 3′, the second package device 3″ and the chip 31. Further, the glue film 17 is formed on the first surface 12 of the carrier 2a to encapsulate the recess 13 to protect the device in the recess 13.

Please refer to FIG. 6B. FIG. 6B is a cross-sectional view of another embodiment of the module with a plurality of stacked package devices. As shown in FIG. 6B, the plane of recess walls 15a, 15b, 15c of the carrier 1a of the module 4′ with a plurality of stacked package devices can be designed as the inclined surface with an angle θ. Thus, when the position for the chip 31 or the package device 3 is located in the carrier 1a with slightly error, the chip 31, the first package device 3′ or the second package device 3″ can slide in a suitable position by the inclined surface of the recess walls 15a, 15b, 15c.

According to abovementioned, the first package device 3′ and the second package device 3″ belong to the different embodiments for the package device 3 as shown in FIG. 5, the different between the first package device 3′ and the second package device 3″ is that the size of the substrate 2, 2′, 2″ is to be adjusted according to the distance between the platforms which is to be configured, such that the first package device 3′ and the second package device 3″ has different size respectively. Moreover, the first platform 133 of the carrier 1a merely is packaged according to above package process. That is, the module 4 with the plurality of stacked package devices and the module 4′ with the plurality of package devices are different from the structure in FIG. 6A or in FIG. 6B. The module 4 with the plurality of stacked package devices and the module 4′ with the plurality of package devices includes a first package device 3′ but not includes the second package device 3″, but the efficiency of the present invention are not to be affected.

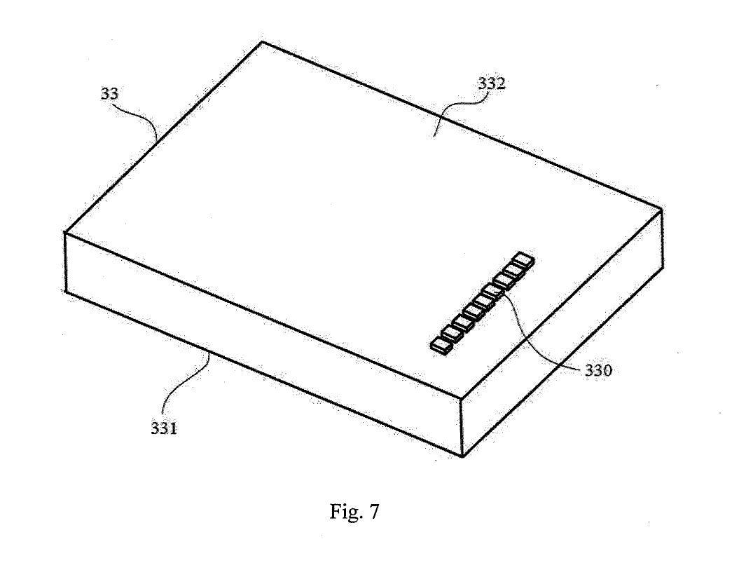

Then, please refer to FIG. 7. FIG. 7 is a vertical view of the second embodiment of the chip of the present invention. As shown in FIG. 7, the chip 33 is obtained by cutting the wafer which has been completed the semiconductor manufacturing process. The chip 33 includes a top 331 and a bottom 332 opposite to the top 331, and the plurality of pads 330 is disposed on the bottom 332. In an embodiment, the plurality of pads 330 is disposed on one end of the chip 33 which is corresponding to the desired connections (not shown) on the arrangement region. For example, the configuration of the plurality of pads 330 is corresponding to the plurality of metal connections 132 on the chip arrangement region 131.

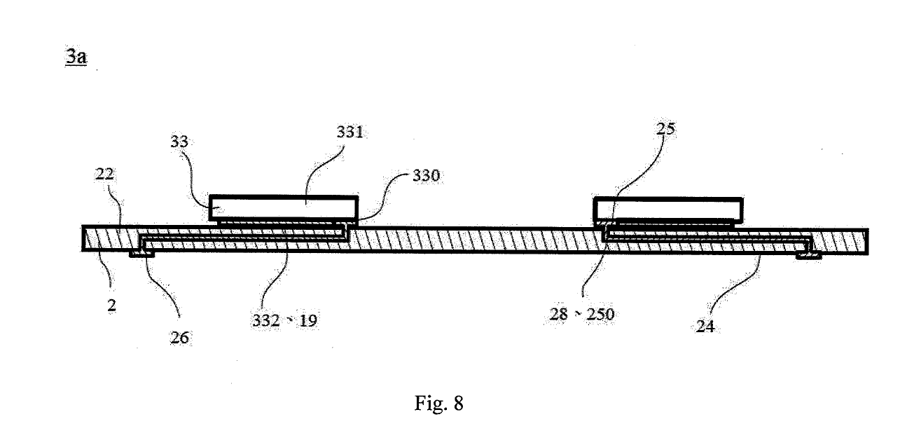

Next, please refer to FIG. 8. FIG. 8 is a cross-sectional view of the second embodiment of the package device. As shown in FIG. 8, the package device 3a includes a chip 33, and the substrate 2 as shown in FIG. 4A and FIG. 4B. As shown in FIG. 4A, the plurality of chip connections 25 on the third surface 22 of the substrate 2 is arranged two different regions. A buffer material 19 is formed near the plurality of chip connections on the region and each the plurality of pads 330 of each region on the bottom 332 of the chip 32 is corresponded to each other. Obviously, two chips 33 can be disposed on the third surface 22 of the substrate 2 to allow each the plurality of pads 330 of two chips 33 that is electrically connected with the plurality of chip connections 25 to form a package device 3a as shown in FIG. 8.

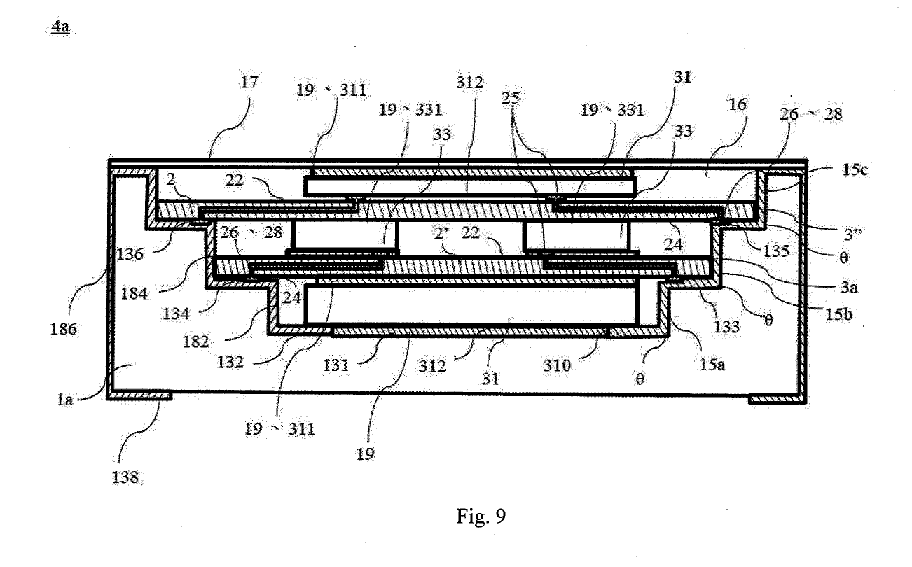

Then, please refer to FIG. 9. FIG. 9 is a cross-sectional view of second embodiment of the module with a plurality of stacked package devices. As shown in FIG. 9, the recess 13 of the module 4a with a plurality of stacked package devices includes a chip 31, a package device 3a, a second package device 3″. The connection relationship between each component is described as below. the different between the module 4a with a plurality of stacked package devices and the module 4 with a plurality of stacked package devices is that the package device 3a is disposed on the first platform 133 for the module 4a with a plurality of stacked package device, in which the fourth surface 24 of the substrate 2 of the package device 3a is opposite to the first platform 133 and each the plurality of carrier connections 26 on the fourth surface 24 is electrically connected with one of the plurality of metal connections 134 on the first platform 133. Then, the buffer material 19 is selectively formed on the top 331 of the two chips 33. Because the height between the second platform 135 and the first platform 133 can be designed as same as that of the package device 3a, the buffer material 19 is capable of avoiding the vibration during subsequent package process to protect the chip 33 from the damaging and the component, such that the component is to be packaged that is fixed the chip 33 of the package device 3a. Of course, the buffer material 19 can form on the third surface 22 of the bottom of the top component of two chips 33 in subsequent package process. For example, when the second package device 3″ is arranged for the module 4a with a plurality of stacked package device, the buffer material 19 is formed on the fourth surface 24 o the substrate 2″ of the second package device 3″ that is relative to the chip 33 of the package device 3a and the package device 3″ is disposed on the second platform 135. For the module 4a with the plurality of stacked package devices, the arrangement of the chip 31 is disposed on the carrier 1a on the chip arrangement region and the second package device 3″ and other components are disposed on the second platform 135 is same as that of the module 4 with a plurality of stacked package devices and thus, it is not to be described herein. Furthermore, the carrier 1a only includes a first platform that is packaged according to above package processes. That is, the module 4a with the plurality of stacked package devices may be different from the module in FIG. 9. The module merely includes the package device 3a but not includes the second package device 3″, and the efficiency of the present invention is not to be affected.

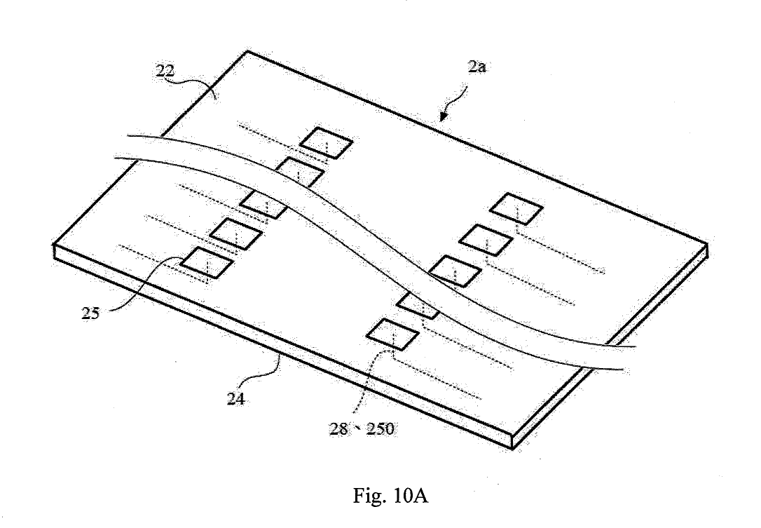

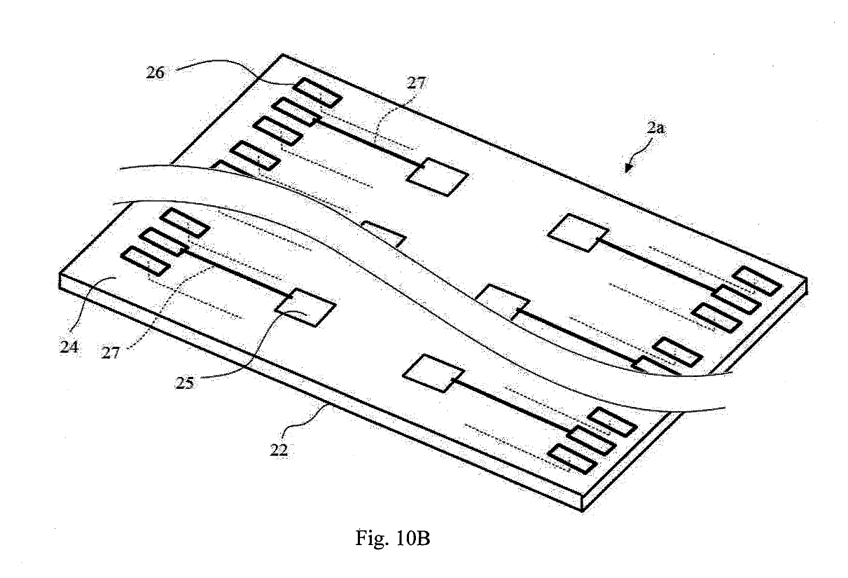

Please refer to FIG. 10A and FIG. 10B. FIG. 10A is a top view of the second embodiment of the substrate and FIG. 10B is a vertical view of the second embodiment of the substrate. As shown in FIG. 10A, the substrate 2a includes a third surface 22 and a fourth surface 24 opposite to the third surface, in which the structure of the third surface 22 of the substrate 2a is similar to the third surface 22 of the substrate 2 and it is not to be described herein. The fourth surface 24 of the substrate 2a includes a plurality of carrier connections 26 and a plurality of chip connections 25 thereon. The number of the plurality of chip connections 25 on the fourth surface 24 of the substrate 2a is less than the number of the plurality of carrier connections 26, and each the plurality of chip connections 25 on the fourth surface of the substrate 2a is electrically connected with the plurality of carrier connections 26 by the plurality of metal wires 27. Obviously, the portion of the plurality of carrier connections 26 is not electrically connected with the plurality of chip connections 26 on the fourth surface 24 of the substrate 2a, and the portion of the plurality of connected carrier connections 26 is not electrically connected with the plurality of chip connections 25 that is electrically connected with the plurality of chip connections 25 on the third surface 22 through the metal material (not shown) within the plurality of substrate through holes 28.

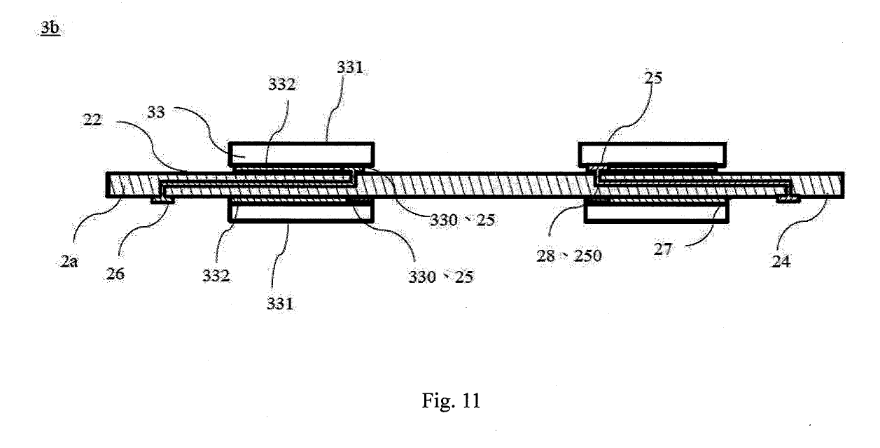

Please refer to FIG. 11. FIG. 11 is a cross-sectional view of the third embodiment of package device. As shown in FIG. 11, for the package device 3b, the two chips 33 are disposed on the third surface 22 as the configuration of the package device 3a. Another two chips 33 are further disposed on the fourth surface 24. The bottom 332 of the chip 33 on the fourth surface 24 of the substrate 2b is opposite to the fourth surface 24 to allow the plurality of pads 330 on the bottom 332 of the chip 33 that is electrically connected with the plurality of chip connections 25 on the fourth surface 24, such that the four chips 33 of the package device 2b is configured as shown in FIG. 11.

The package device 3, 3a, 3b can configure with different substrates 2, 2a and configure with at least one chip 31, 33 thereon, but the number of the chip 31, 33 on the third surface 22 or fourth surface 24 of the substrate 2, 2a is not limited herein.

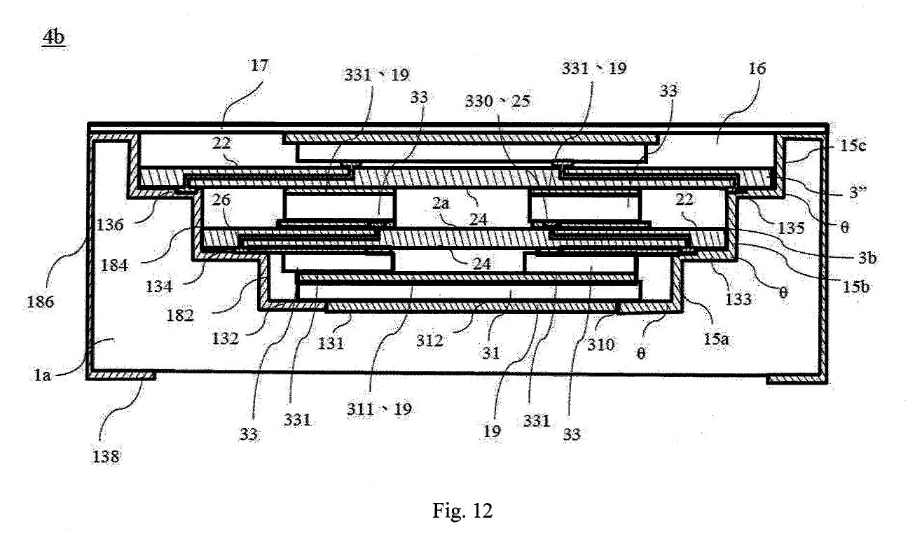

Then, please refer to FIG. 12. FIG. 12 is a cross-sectional view of the third embodiment of the module with a plurality of stacked package devices. As shown in FIG. 12, the recess 13 of the module 4b with the plurality of stacked package device includes a chip 31, a package device 3b, a second package device 3″. The connection relationship between each component is described as below. The different between the module 4b with a plurality of stacked package devices and the module 4 with a plurality of stacked package devices in FIG. 6 is that the package device 3b is disposed on the first platform 133 for the module 4b with the plurality of stacked package devices, in which the fourth surface 24 of the substrate 2a of the package device 3b is opposite to the first platform 133 and a buffer material 19 is formed on the top 311 of the chip 31 of the first chip arrangement region 131. Of course, the buffer material 19 is formed on the top 311 of the chip 33 on the fourth surface 24 of the package device 3b to allow each the plurality of carrier connections 26 on the fourth surface 24 that is electrically connected with one of the plurality of metal connections 134 on the first platform 133. Meanwhile, the height from the first platform 133 to the first chip arrangement region 131 can be designed as the same that of the component which is to be packaged. The buffer material 19 is capable of fixing the chip 31 on the first chip arrangement region 131 and the chip 33 on the fourth surface 24 of the package device 3b. Then, the buffer material 19 is respectively formed on the top 331 of two chips 33 on the third surface 22 of the package device 3b. the height between the second platform 135 and the first platform 133 can be designed as the same that of the package device 3b, and thus, the buffer material 19 is capable of avoiding vibration in subsequently package process to protect the chip from the damaging and the component is to be packaged that is fixed the chip 33 on the third surface 22 of the package device 3b. Of course, the buffer material 19 is first formed on the bottom of the top component (not shown) of two chips 33 on the third surface 22 during the package process. For example, the second package device 3″ is configured for the module 4b with a plurality of stacked package devices, the buffer material 19 is formed on the fourth surface 24 of the substrate 2″ of the second package device 3″ that is relatively to the chip 33 on the third surface 22 of the package device 3b and then the package device 3″ is disposed on the second platform 135. For the module 4b with the plurality of stacked package devices, the arrangement of the carrier 1a is disposed on the chip 31 on the chip arrangement region 131 and the arrangement for the second package device 3″ and other components are disposed on the second platform 135 are identical to the arrangement for the module 4 with the plurality of stacked package devices and it is not to be described herein. Moreover, the carrier 1a only includes the first platform 133 that is to be packaged according to above package process. That is, the structure of the module 4b with the plurality of stacked package devices may be different from the structure in FIG. 12, the structure of the module 4b with the plurality of stacked package devices merely includes the package device 3b but not includes the second package device 3″ and the efficiency of the present invention is not to be affected.

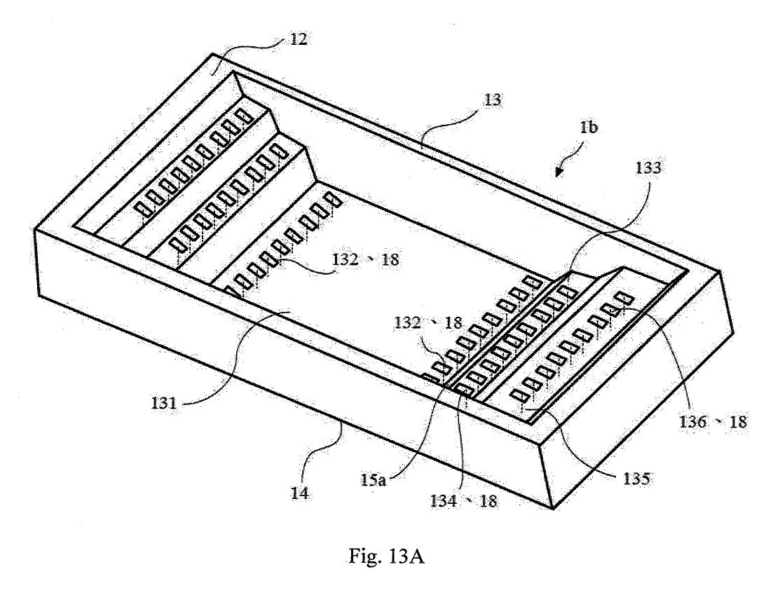

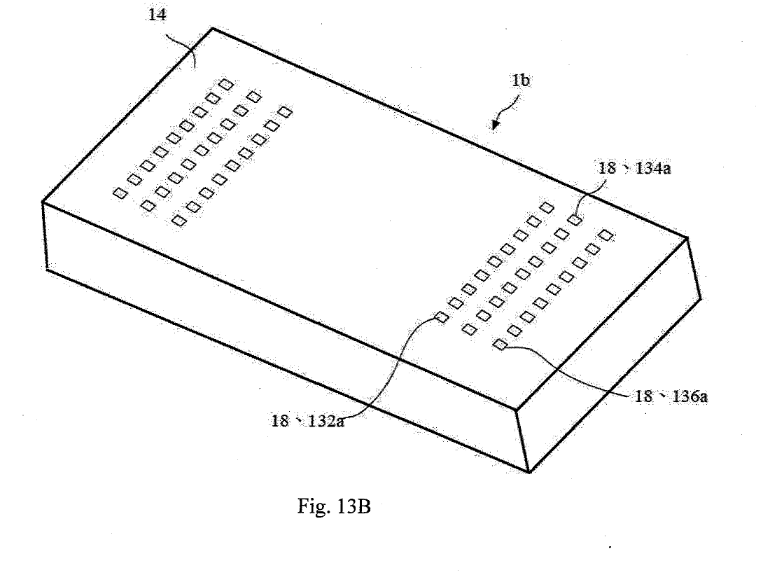

Then, please both refer to FIG. 13A and FIG. 13B. FIG. 13A is a top view of the second embodiment of the carrier and FIG. 13B is a vertical view of the second embodiment of the carrier. As shown in FIG. 13A and FIG. 13B, the plurality of metal connections 132 is disposed near two sides of the first platform 133, the plurality of metal connections 134 is disposed on two sides of the first platforms 133, and the plurality of metal connections 136 is disposed on two sides of the second platform 135. Each the plurality of metal connections 132, 134, 136 is extended to the second surface 14 of the carrier 1b through the plurality of carrier through holes 18 to form a plurality of metal connections 132a, 134a, 136a which is disposed in a neat arrangement on the second surface as shown in FIG. 13B.

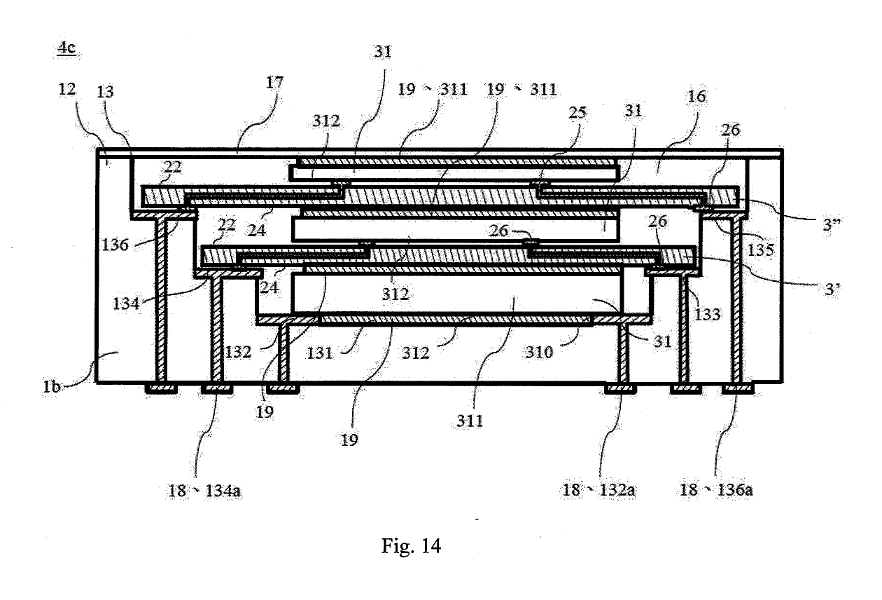

Next, please refer to FIG. 14. FIG. 14 is a cross-sectional view of the fourth embodiment of the module with a plurality of stacked package devices. As shown in FIG. 14, the module 4c with a plurality of stacked package devices includes a carrier 1 that has a recess 13 therein, a chip 31 and at least one package device 3. Obviously, the module 4c with the plurality of stacked package devices includes a plurality of chips 31, in which the chip 31 is flipped on the first chip arrangement region 131 of the carrier 1b, the first package device 3′ is disposed on the first platform 133 and the second package device 3″ is disposed on the second platform 135. For the connection relationship between each components and carrier 1b is identical to that of each component and carrier 1a of the module 4 with the plurality of stacked package device and thus it is not described herein. Further, the carrier 1b can also be packaged according to above package process when the carrier 1b only includes a first platform. That is, the module 4c with the plurality of stacked package device is different from the structure of FIG. 14, which only includes a first package device 3′ and not includes a second package device 3″ and the efficiency of the present invention is not to be affected.

As aforementioned, the module 4, 4′, 4a, 4b with the plurality of stacked package devices are disposed on the other board (not shown) after package process has been completed, and are electrically connected with the connections (not shown) on the board (not shown) by the plurality of metal connections 138 or the plurality of metal connections 132a, 134a, 136a. Meanwhile, the plurality of metal connections 186 is exposed out of the external of the module 4, 4′, 4a, 4b with the plurality of stacked package devices to allow the module 4, 4′,4a, 4b with the plurality of stacked package devices is electrically connected with the connections (not shown). In addition to reducing the fault that is caused by a short circuit, but also to increase the circuit transmission efficiency.

The number of the platforms is not limited in the carrier 1, 1a, 1b. That is, according to the requirement, the carrier 1, 1a, 1b not only includes the first platform 133 and the second platform 135 but also adds the third platform (not shown), the fourth platform (not shown) or more platforms to allow more chips or package devices that can be packaged in the carrier 1, 1a, 1b. In addition, the types and size of the chips 31, 33 are not to be limited herein.

As aforementioned, the substrate 2, 2′, 2″, 2a is used for the package device 3, 3a, 3b, the first package device 3′, or the second package device 3′ of the present invention utilizes according to the width selection the platform. Thus, the package device 3, 3a, 3b, the first package device 3′ or the second package device 3″ may have different size. the chip or components is disposed on the bottom of the package device that is provide an additional support for the substrate 2, 2′, 2″, 2a due the substrate 2, 2′, 2″, 2a cab be FPC (flexible printed circuit), such that the substrate 2, 2′, 2″, 2a are not suspended over the platform to cause the collapse.

As aforementioned, the carriers 1, 1a, and 1b can be set via the standardization process and manufactured by the outside packaging factory manufacturers which can effectively reduce the production cost. The size of the package production can also be standardized by the standardized setting to increase the efficiency of the package vendor and the vendor which using the packaging product. Thus, is the chip 31 or package device 3, 3a, 3b are assembled into the carrier 1, 1a, 1b with using the alignment process such that the alignment process of assembling other components can be omitted to increase the work efficiency of the package vendor and the vendor using the package product, and the module setting can also ensure the connection between each the plurality of pads and each the plurality of connections to increase the reliability. Meanwhile, the chip 31, 33 or package device 3, 3a, 3b is disposed in the carrier 1, 1a, 1b completely, and is protected by the buffer material 19 or glue 16 to increase the reliability of the package product, in which the module 4, 4′, 4a, 4b with the plurality of stacked package device 3 utilizes the buffer material 19 to provide the protection of the chip and the package cost is also to be reduced.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A module with a plurality of stacked package device, comprising:
a carrier having a first surface and a second surface opposite to said first surface, said first surface having a recess and an edge around said recess to allow a first chip arrangement region that is formed in said recess, a plurality of first metal connections is disposed on a bottom of said recess and said plurality of first metal connections is redistributed two sides of said recess and a pair of platforms is disposed adjacent to two sides of chip arrangement region respectively, such that a pair of first recess walls is formed between said pair of platforms and said chip arrangement region, a pair of second recess walls is disposed between said edge and said platforms and said plurality of first metal connections is exposed, a height of said pair of platforms is higher than that of said chip arrangement region, and a plurality of second metal connections is disposed on said pair of platforms respectively, wherein each said plurality of first metal connections on same side is corresponding to each said plurality of second metal connections, and each said plurality of first metal connections is electrically connected with each said plurality of second metal connections by a first metal wire;
a first chip having a top and a bottom and a plurality of first pads is disposed on said bottom of said first chip, said first chip is flipped on said chip arrangement region and said plurality of first pads is electrically connected with said plurality of first metal connections; and
a package device having a second chip and a substrate, said second chip having a top and a bottom and a plurality of second pads is disposed on said bottom of said second chip, said substrate having a third surface and a fourth surface opposite to said third surface and a plurality of through holes is passed through said third surface and said fourth surface of said substrate, a plurality of chip connections on said third surface of said substrate and said plurality of said chip connections is extended through said through holes to said fourth surface to form a plurality of carrier connections, wherein said plurality of chip connections is electrically connected with said plurality of second pads and said plurality of carrier connections is electrically connected with said plurality of second metal connections of said carrier;
wherein, each said plurality of second metal connections is further electrically connected with a plurality of second metal wires, said plurality of second metal wires is disposed from said platform of said carrier through said edge to said second surface of said carrier, and each said plurality of second metal wires is disposed on one end of said second surface of said carrier to form a plurality of third metal connections.

2. The module with the plurality of stacked package device according to claim 1, wherein an angle between said first recess wall and said chip arrangement region is in range from 90 degree to 135 degree.

3. The module with the plurality of stacked package device according to claim 1, wherein said recess of said carrier further includes a glue to encapsulate said first chip and said package device.

4. The module with the plurality of stacked package device according to claim 1, wherein said first surface of said carrier further includes a glue film to encapsulate said recess.

5. The module with the plurality of stacked package device according to claim 1, wherein a buffer material is formed between said first chip and said package device.

6. A module with a plurality of stacked package device, comprises:
a carrier having a first surface and a second surface opposite to said first surface, a recess is formed on said first surface of said recess and an edge is disposed around said recess such that a chip arrangement region is disposed in said recess, a plurality of first metal connections is disposed on a bottom of said recess and said plurality of first metal connections is redistributed on two sides of said recess and a pair of platforms is disposed adjacent to two sides of said chip arrangement region such that a pair of first recess walls is disposed between said pair of said platforms and said chip arrangement region and a second recess walls is formed between said edge and said pair of platforms and said plurality of first metal connections is exposed, a height of said pair of platforms is higher than said chip arrangement region, a plurality of second metal connections is disposed on said pair of platforms respectively, wherein each said plurality of first metal connections on one side is corresponding to each said plurality of second metal connections and each said plurality of first metal connections is electrically connected with said plurality of said second metal connections by a first metal wire;
a first chip having a top and a bottom and a plurality of first pads is disposed on said bottom of said first chip, said first chip is flipped on said chip arrangement region to allow said plurality of first pads that is electrically connected with said plurality of first metal connections; and
a package device having a pair of second chips and a substrate, each said pair of second chips having a top and a bottom and a plurality of second pads is disposed on said bottom thereof, said substrate having a third surface and a fourth surface opposite to said third surface and a plurality of substrate through holes is passed through from said third surface to said fourth surface of said substrate, a plurality of first chip connections is disposed on said third surface of said substrate and said plurality of first chip connections is extended to said fourth surface of said substrate through said plurality of substrate through holes to form a plurality of carrier connections, wherein said plurality of first chip connections is electrically connected with said plurality of second pads of each said pair of second chips and said plurality of first carrier connections is electrically connected with said plurality of second metal connections of said carrier;
wherein each said plurality of second metal connections is further electrically connected with a plurality of second metal wires, said plurality of second metal wires is extended from said platform of said carrier through said edge to said second surface of said carrier and each said plurality of second metal wires is formed on one end of said second surface of said carrier to form a plurality of third metal connections.

7. The module with the plurality of stacked package device according to claim 6, wherein an angle between said first recess wall and said chip arrangement region is in range from 90 degree to 135 degree.

8. The module with the plurality of stacked package device according to claim 6, wherein said fourth surface of said substrate further includes a pair of third chips, a plurality of second chip connections and a plurality of second carrier connections, each said pair of third chips having a top and a bottom and a plurality of third pads is disposed on said bottom of said pair of third chips, each said plurality of second chip connections is electrically connected with each said plurality of second carrier connections by a plurality of metal wires, wherein said plurality of third pads of said pair of third chips is electrically connected with said plurality of second chip connections and both said plurality of second carrier connections and said plurality of first carrier connections are electrically connected with said plurality of second metal connections of said carrier.

9. A module with a plurality of stacked package device, comprises:
a carrier having a first surface and a second surface opposite to said first surface, a recess is formed on said first surface of said carrier and an edge is disposed around said recess such that a chip arrangement region is formed in said recess and a plurality of first metal connections is disposed on a bottom of said recess, said plurality of first metal connections is redistributed on two sides of said chip arrangement region such that a pair of first recess walls is formed between said pair of platforms and said chip arrangement region and a pair of second recess walls is formed between said edge and said pair of platforms and said plurality of first metal connections is exposed, a height of said pair of platform is higher than that of said chip arrangement region and a plurality of second metal connections is disposed on said pair of platforms, wherein each said plurality of first metal connections on same side is corresponding to each said plurality of second metal connections;
a first chip having a top and a bottom and a plurality of pads is disposed on said bottom of said first chip and said first chip is flipped on said chip arrangement region to allow each said plurality of first pads is electrically connected with said plurality of first metal connections;
wherein said carrier further includes a plurality of carrier through holes which is passed through said first surface to said second surface of said carrier, both each said plurality of first metal connections and each said plurality of second metal connections are extended from said plurality carrier through holes to said second surface of said carrier to form a plurality of third metal connections.

10. The module with the plurality of stacked package device according to claim 9, wherein an angle between said first recess wall and said chip arrangement region is in range from 90 degree to 135 degree.
